(19) United States
(12) Patent Application Publication
(10) Pub. No.: US 2026/0101546 A1
(43) Pub. Date: Apr. 9, 2026

(54) TRENCH MOSFET WITH PERIODIC P-ISLAND SHIELDING

(71) Applicant: Renesas Electronics America Inc., Milpitas, CA (US)

(72) Inventors: Kijeong HAN, Morrisville, NC (US); Meng Chia LEE, Dallas, TX (US); Dilip Madhav RISBUD, San Jose, CA (US)

(73) Assignee: RENESAS ELECTRONICS CORPORATION, Tokyo (JP)

(21) Appl. No.: 18/909,153

(22) Filed: Oct. 8, 2024

(51) Int. Cl. H01L 29/06; H01L 21/04; H01L 29/16; H01L 29/66; H01L 29/78

(52) U.S. Cl. CPC H10D 62/109; H10D 12/031; H10D 30/668; H10D 62/8325; H10D 64/01366; H10P 30/2042; H10P 30/21

(57) ABSTRACT

A semiconductor structure includes a silicon carbide semiconductor substrate of a first conductivity type. The semiconductor structure further includes a drift layer of the first conductivity type located above the semiconductor substrate, a channel layer of a second conductivity type located above the drift layer, and a source region of the first conductivity type located above the channel layer. The second conductivity type is opposite to the first conductivity type. A plurality of trenches penetrates through the source region, the channel layer and a portion of the drift region. A gate electrode is located within each of the plurality of trenches via a gate insulating film and a plurality of shielding structures of the second conductivity type is located around the gate electrode. The plurality of shielding structures covers sidewalls and a bottom of the plurality of trenches. The plurality of shielding structures is arranged in an island-like manner.

### BACKGROUND

The present disclosure generally relates to the field of semiconductor devices, and more particularly to trench metal-oxide-semiconductor field-effect transistors (MOSFETs) and their associated shielding techniques.

Trench MOSFETs are widely used in power electronics due to their high efficiency and performance characteristics. These devices are designed to handle high voltages and currents with reduced on-resistance compared to conventional planar MOSFETs. Trench MOSFETs incorporate a vertical structure where the gate electrode is placed within a trench etched into the semiconductor substrate, providing a compact and efficient layout.

Despite their advantages, trench MOSFETs face challenges related to device performance and reliability, particularly in high-density integrated circuits. One critical issue is the management of parasitic capacitances and electric fields that can negatively impact the device's switching performance and overall efficiency.

### SUMMARY

According to an embodiment of the present disclosure, a semiconductor structure includes a semiconductor substrate of a first conductivity type. The semiconductor substrate includes silicon carbide. The semiconductor structure further includes a drift layer of the first conductivity type located above the semiconductor substrate. The semiconductor structure further includes a channel layer of a second conductivity type located above the drift layer. The second conductivity type of the channel layer is opposite to the first conductivity type of the drift layer. The semiconductor structure further includes a source region of the first conductivity type located above the channel layer. The semiconductor structure further includes a plurality of trenches penetrating through the source region, the channel layer and a portion of the drift layer. The semiconductor structure further includes a gate electrode located within each of the plurality of trenches via a gate insulating film. The semiconductor structure further includes a plurality of shielding structures of the second conductivity type located around the gate electrode. The plurality of shielding structures covers sidewalls and a bottom of the plurality of trenches. The plurality of shielding structures is arranged in an island-like manner.

According to another embodiment of the present disclosure, a semiconductor structure includes a plurality of trench structures extending, at least partially, within a stack of doped semiconductor layers. The plurality of trench structures includes first trench structures and second trench structures. The second trench structures are located between two adjacent first trench structures. The semiconductor structure further includes a gate structure disposed within the first trench structures and the second trench structures. The semiconductor structure further includes a plurality of shielding structures embedded, at least partially, within the stack of doped semiconductor layers surrounding the gate structure within the first trench structures. The plurality of shielding structures is separated by a distance selected based on initiating a three-dimensional pinch-off effect between adjacent shielding structures. The gate structure within the second trench structures is surrounded by the stack of doped semiconductor layers.

According to yet another embodiment of the present disclosure, a semiconductor structure includes a semiconductor substrate of a first conductivity type. The semiconductor substrate including silicon carbide. The semiconductor structure further includes a drift layer of the first conductivity type located above the semiconductor substrate. The semiconductor structure further includes a channel layer of a second conductivity type located above the drift layer. The second conductivity type of the channel layer being opposite to the first conductivity type of the drift layer. The semiconductor structure further includes a source region of the first conductivity type located above the channel layer. The semiconductor structure further includes a plurality of trenches penetrating through the source region, the channel layer and a portion of the drift layer. The semiconductor structure further includes an insulating region lining the plurality of trenches. The insulating region includes a bottom portion, a lower side portion and an upper side portion. The semiconductor structure further includes a gate electrode located within each of the plurality of trenches lined with the insulating region. The semiconductor structure further includes a plurality of shielding structures of the second conductivity type located around the gate electrode. The plurality of shielding structures covers sidewalls and a bottom of the plurality of the trenches. The plurality of shielding structures is arranged in an island-like manner.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a cross-sectional view of a semiconductor structure after forming a stack of doped semiconductor layers, according to an embodiment of the present disclosure;

FIG. 2 is a cross-sectional view of the semiconductor structure after forming heavily-doped semiconductor regions within the stack of doped semiconductor layers, according to an embodiment of the present disclosure;

FIG. 3A is a top-down view of the semiconductor structure after forming trench structures and shielding structures based on a first distribution pattern, according to an embodiment of the present disclosure;

FIG. 3B is a cross-sectional view of the semiconductor structure taken along line A-A′, as depicted in FIG. 3A according to an embodiment of the present disclosure;

FIG. 4A is a cross-sectional view of the semiconductor structure taken along line A-A′, as depicted in FIG. 3A, describing an alternate way of forming the trench structures, according to an embodiment of the present disclosure;

FIG. 4B is a cross-sectional view of the semiconductor structure taken along line A-A′, as depicted in FIG. 3A, depicting an alternate way of forming heavily-doped semiconductor regions, according to an embodiment of the present disclosure;

FIG. 5 is a cross-sectional view of the semiconductor structure taken along line A-A′, as depicted in FIG. 3A, after forming an insulating layer within the trench structures, according to an embodiment of the present disclosure;

FIG. 6A is a cross-sectional view of the semiconductor structure taken along line A-A′, as depicted in FIG. 3A, after forming a gate electrode, an interlevel dielectric layer, a source electrode, and a drain electrode, according to an embodiment of the present disclosure;

FIG. 6B is a cross-sectional view of the semiconductor structure taken along line B-B′, as depicted in FIG. 3A, according to an embodiment of the present disclosure;

FIG. 6C is a cross-sectional view of the semiconductor structure taken along line A-A′, as depicted in FIG. 3A, depicting an insulating region having sections of varying thickness, according to an embodiment of the present disclosure;

FIG. 6D is a cross-sectional view of the semiconductor structure taken along line A-A′, as depicted in FIG. 3A, depicting the formation of shielding regions within source region, according to an embodiment of the present disclosure;

FIG. 6E is a cross-sectional view of the semiconductor structure taken along line A-A′, as depicted in FIG. 3A, describing the formation of heavily-doped semiconductor regions between adjacent shielding regions, according to an embodiment of the present disclosure;

FIG. 6F is a cross-sectional view of the semiconductor structure taken along line A-A′, as depicted in FIG. 3A, describing an alternate configuration of shielding structures including shielding regions based on the first distribution pattern, according to another embodiment of the present disclosure;

FIG. 6G is a cross-sectional view of the semiconductor structure taken along line A-A′, as depicted in FIG. 3A, depicting the alternate configuration of shielding structures including shielding regions based on the first distribution pattern and the insulating region having sections of varying thickness, according to another embodiment of the present disclosure;

FIG. 7A is a top-down view of a semiconductor structure depicting trench structures and shielding structures formed based on a second distribution pattern, according to an embodiment of the present disclosure;

FIG. 7B is a cross-sectional view of the semiconductor structure taken along line C-C′ as depicted in FIG. 7A, according to an embodiment of the present disclosure;

FIG. 7C is a cross-sectional view of the semiconductor structure taken along line D-D′ as depicted in FIG. 7A, according to an embodiment of the present disclosure;

FIG. 7D is a cross-sectional view of the semiconductor structure taken along line C-C′, as depicted in FIG. 7A, depicting the insulating region having sections of varying thickness, according to an embodiment of the present disclosure;

FIG. 7E is a cross-sectional view of the semiconductor structure taken along line C-C′, as depicted in FIG. 7A, describing the alternate configuration of shielding structures including shielding regions based on the second distribution pattern, according to an embodiment of the present disclosure;

FIG. 7F is a cross-sectional view of the semiconductor structure taken along line C-C′, as depicted in FIG. 7A, depicting the alternate configuration of shielding structures including shielding regions based on the second distribution pattern and the insulating region having sections of varying thickness, according to an embodiment of the present disclosure;

FIG. 8 is a flowchart depicting operational steps for the fabrication of the semiconductor structure, according to an embodiment of the present disclosure; and

FIG. 9 is a flowchart depicting alternate operational steps for the fabrication of the semiconductor structure, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In trench MOSFETs, parasitic capacitances between the gate, source, and drain can significantly impact performance. The electric field distributions within the trench structure may lead to reduced breakdown voltage and increased leakage currents, which can compromise both the reliability and efficiency of the device. A key challenge in trench MOSFETs is maintaining oxide reliability, as the electric field tends to concentrate at the bottom corners of the trench when the device is in the off-state.

To mitigate these issues, various shielding techniques have been developed. One common approach involves the use of P-type regions or “shielding” layers within the trench to manage electric field distribution and reduce parasitic capacitances. Existing shielding techniques for trench MOSFETs, while addressing some of the parasitic capacitance issues, still present challenges in terms of fabrication complexity and performance optimization. Conventional P-type shielding regions are typically placed in fixed configurations, which may not fully optimize electric field management across varying operating conditions and device sizes. For example, although placing a P-type shielding region underneath the trench can protect the oxide region, it also increases the sheet resistance (Rsp) due to its width typically exceeds the width of the trench.

Embodiments of the present disclosure introduces a trench MOSFET design that incorporates periodic P-island shielding to address the above problems. Specifically, embodiments of the present disclosure provide P-type shield regions formed in an island-like manner around the trench. These P-island shielding regions are strategically positioned to protect the oxides' electric field at the corners of the trench and in the areas adjacent to these corners. In some embodiments, the P-island shielding regions are arranged in a staggered distribution pattern, while in other embodiments they follow an aligned distribution pattern. The spacing between these P-island regions is selected to create a three-dimensional (3D) pinch-off effect, which enhances protection for both the corners of the trench and the adjacent areas. This approach aims to improve control over electric field distribution and reduce parasitic effects, thereby enhancing the performance and reliability of trench MOSFETs without adding significant complexity to the manufacturing process. More particularly, embodiments of the present disclosure effectively manage electric fields and parasitic capacitances while maintaining high device density and performance characteristics.

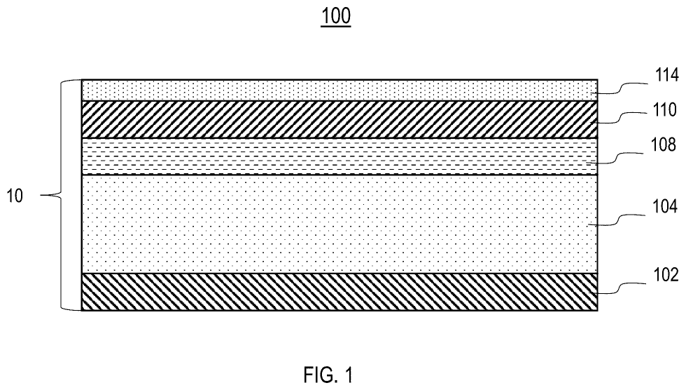

Embodiments by which a trench MOSFETs with periodic P-island shielding can be formed is described in detail below by referring to the accompanying drawings in FIGS. 1-9.

Referring now to FIG. 1, a cross-sectional view of a semiconductor structure 100 is shown at an intermediate step during a semiconductor manufacturing process, according to an embodiment of the present disclosure. More particularly, FIG. 1 depicts an intermediate step during the formation of a silicon carbide trench MOSFET with periodic p-island shielding.

At this step of the manufacturing process, the semiconductor structure 100 includes alternating layers of a semiconductor material having different dopant concentrations arranged in a stack 10 of doped semiconductor layers. Various types of semiconductor fabrication operations can be used to form the semiconductor structure 100 as depicted in FIG. 1. In particular, various deposition and implantation steps have been conducted to form the stack 10 of doped semiconductor layers.

According to an embodiment, the stack 10 includes a first doped semiconductor layer of a first conductivity type made of silicon carbide (SiC) with an added impurity concentration. The first doped semiconductor layer serves as a semiconductor substrate (hereinafter “substrate”) 102 of the semiconductor structure 100. A thickness of the initial substrate 102 is approximately 350 μm. The substrate 102 can be grinded to approximately 100 mm during backside processing steps. The impurity concentration in the substrate 102 can vary between approximately 1×10¹⁸ cm⁻³ to approximately 1×10¹⁹ cm⁻³. The first conductivity type can be P-type or N-type. It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties.

The stack 10 further includes a second doped semiconductor layer of the first conductivity type. The second doped semiconductor layer serves as a drift region 104 of the semiconductor structure 100. Drift region 104 is formed above and in contact with the substrate 102. The drift region 104 is made of silicon carbide with an added impurity concentration that is lower than the impurity concentration of substrate 102. In general, drift region 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift region 104 can be formed by chemical vapor deposition (CVD) of the semiconductor material (i.e., SiC). A thickness of the drift region 104 is determined by the device voltage rating. For example, the thickness of the drift region 104 can be approximately 10 μm for 1.2 kV rated devices. The impurity concentration of the drift region 104 can be approximately 1×10¹⁶ cm⁻³ for 1.2 kV rated devices. However, the impurity concentration of the drift region 104 is not limited to this value and may be in a range of approximately 1×10¹⁴ cm⁻³ to approximately 1×10¹⁷ cm⁻³ depending on the device voltage rating.

The stack 10 further includes a third doped semiconductor layer of the first conductivity type. The third doped semiconductor layer serves as a junction field effect transistor (JFET) region 108 of the semiconductor structure 100. The JFET region 108 is formed above and in contact with the drift region 104. In some instances, JFET region 108 can be formed with a higher donor doping of the first conductivity type that can vary between approximately 1×10¹⁵ cm⁻³ and approximately 1×10¹⁸ cm⁻³. A thickness of the JFET region 108 is approximately 0.1 μm to approximately 3.5 μm.

The stack 10 further includes a fourth doped semiconductor layer of a second conductivity type. The fourth doped semiconductor layer serves as a base region 110 of the semiconductor structure 100. The base region 110 is formed above the JFET region 108. A thickness of the base region 110 is approximately 0.1 μm to approximately 1.0 μm. The impurity concentration of the base region 110 is approximately 1×10¹⁷ cm⁻³ or higher. The second conductivity type can be P-type or N-type.

The stack 10 further includes a fifth doped semiconductor layer of the first conductivity type. The fifth doped semiconductor layer serves as a source region 114 of the semiconductor structure 100. The source region 114 is formed above and in contact with the base region 110. A thickness of the source region 114 is approximately 0.1 μm to approximately 0.5 μm. Source region 114 may include a heavily-doped semiconductor layer of the first conductivity type. A dopant concentration of source region 114 can vary, for example, between 1×10¹⁹ cm⁻³ and 1×10²¹ cm⁻³.

In one or more embodiments, the different impurity or dopant concentrations in the stack 10 of doped semiconductor layers can be achieved by ion implantation or diffusion of impurity ions or dopants. For example, in embodiments in which the first conductivity type is N-type and the second conductivity type is P-type, N-type dopants such as phosphorus (P) or arsenic (As) can be implanted into one or more semiconductor layers of the stack 10 to form the N-type doped semiconductor layers, while P-type dopants such as boron (B), aluminum (Al) or gallium (Ga) are implanted into one or more semiconductor layers of stack 10 to form the P-type doped semiconductor layers.

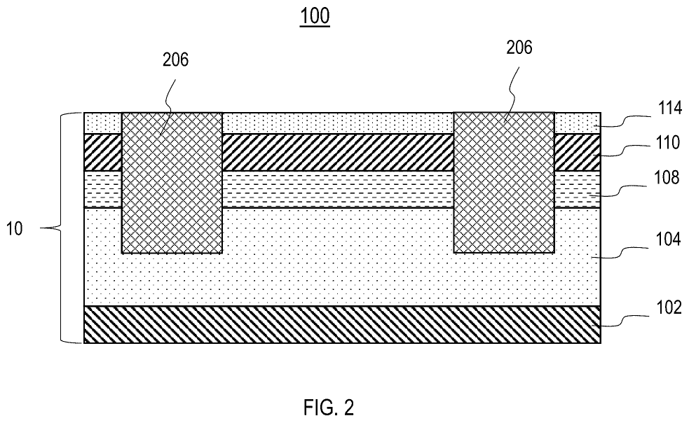

Referring now to FIG. 2, a cross-sectional view of the semiconductor structure 100 is shown after forming heavily-doped semiconductor regions 206 within the stack 10, according to an embodiment of the present disclosure.

In this embodiment, an ion implantation process is conducted on the semiconductor structure 100 to form heavily-doped semiconductor regions 206 within the stack 10 of doped semiconductor layers. Each of the heavily-doped semiconductor regions 206 embedded within stack 10 extend from a top surface of source region 114 through a predetermined depth within the drift region 104. The predetermined depth of the heavily-doped semiconductor regions 206 within drift region 104 may be of approximately 0.8 μm to approximately 3.5 μm.

Thus, heavily-doped semiconductor regions 206 can be formed using various types of ion implantation processes by which such depth can be achieved. For example, in an embodiment, a random ion implantation process can be used to form heavily-doped semiconductor regions 206. In another embodiment, a channeled ion implantation process can be used to form heavily-doped semiconductor regions 206. Heavily-doped semiconductor regions 206 can be formed with an impurity concentration of the second conductivity type varying between approximately 1×10¹⁵ cm⁻³ and approximately 1×10¹⁹ cm⁻³ depending on the doping concentration of drift region 104. More particularly, the impurity concentration of heavily-doped semiconductor regions 206 is at least 10 times greater than the impurity concentration in the drift region 104.

For illustration purposes only, without intent of limitation, two heavily-doped semiconductor regions 206 are shown in the figure. It may be understood that any number of heavily-doped semiconductor regions 206 can be formed in the semiconductor structure 100 to satisfy design requirements.

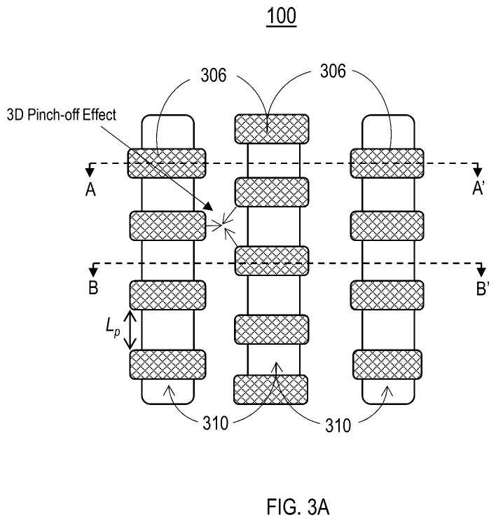

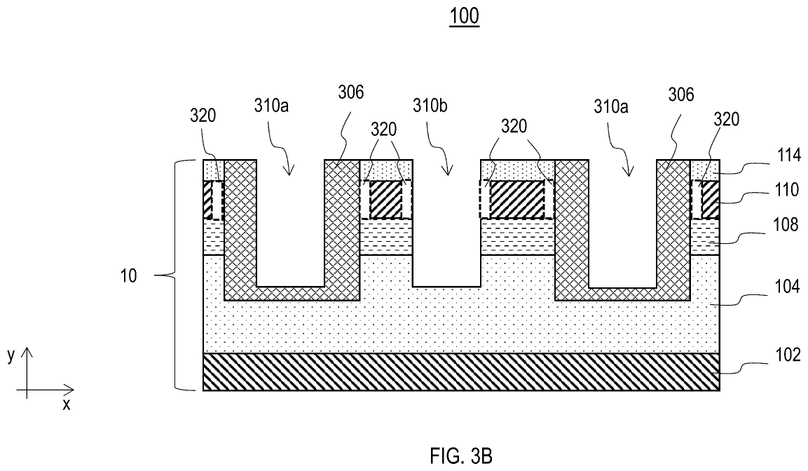

Referring now to FIGS. 3A-3B simultaneously, different views of the semiconductor structure 100 are shown after forming a plurality of trench structures 310 and shielding structures 306 based on a first distribution pattern, according to an embodiment of the present disclosure. In this embodiment, FIG. 3A is a top-down view of the semiconductor structure 100; and FIG. 3B is a cross-sectional view of the semiconductor structure 100 taken along line A-A′, as depicted in FIG. 3A.

In this embodiment, the plurality of trenches (hereinafter “trenches”) 310 includes a first plurality of trenches (hereinafter “first trenches”) 310a formed within heavily-doped semiconductor region 206 (FIG. 2) and a plurality of second trenches (hereinafter “second trenches”) 310b formed within the stack 10 of doped semiconductor layers. The process of forming trenches 310 can involve exposing a pattern on a photoresist layer, transferring the pattern to a hardmask layer (not shown) and then to the stack 10 including the heavily-doped semiconductor regions 206 (FIG. 2) using lithography and reactive-ion etching (RIE) processing.

FIG. 3B shows first trenches 310a being formed within each heavily-doped semiconductor region 206. As shown in the figure, portions of the heavily-doped semiconductor regions 206 (FIG. 2) remaining in the semiconductor structure 100 form a shielding structure (or shielding region) 306 around the first trenches 310a. More particularly, each shielding structure 306 is disposed along opposite sidewalls 312 and along a bottom surface 314 of first trench 310. Stated differently, shielding structures 306 cover a perimeter of first trenches 310a defined by opposite sidewalls 312 and bottom surface 314. As depicted in FIG. 3B, an upper portion of shielding structures 306 is adjacent to JFET region 108, base region 110 and source region 114, while a bottom portion of shielding structures 306 is surrounded by drift region 104.

Second trenches 310b exposes opposite sidewalls of source region 114, base region 110, JFET region 108, upper sidewalls of drift region 104 and an upper surface of drift region 104.

In one or more embodiments, a depth (as measured in the-y direction) of first trenches 310a and second trenches 310b into the stack 10 can vary between approximately 0.8 μm to approximately 3.0 μm. A width (as measured in the x direction) of first trenches 310a and second trenches 310b can vary between approximately 0.3 mm to approximately 2.0 mm.

After forming first trenches 310a and second trenches 310b, a thickness of the remaining heavily-doped semiconductor material forming shielding structures 306 may vary between approximately 0.1 mm to approximately 1.0 mm.

According to an embodiment, a channel region 320 is defined within base region 110 after forming the first trenches 310a and second trenches 310b in the semiconductor structure 100. The channel region 320 is disposed adjacent to first and second trenches 310a, 310b and in contact with JFET regions 108 and source region 114. Thus, a size of the fourth doped semiconductor layer of stack 10 providing the base region 110 can be in a range that provides a short channel effect.

For simplicity, the elements first trenches 310a and second trenches 310b will hereafter be collectively referred to as “trenches 310”.

With continued reference to FIG. 3A, shielding structures 306 shaped in an island-like manner are arranged around trenches 310 following a first distribution pattern. In this embodiment, the first distribution pattern includes a staggered distribution pattern. Specifically, as depicted in FIG. 3A, shielding structures 306 are formed in a staggered or checkerboard pattern of isolated clusters or segments, with each cluster resembling an “island”. The island-like shielding structures 306 are positioned in non-contiguous regions within trenches 310, with each shielding structure 306 being separated by a gap or distance Lₚ, as shown in FIG. 3A.

The distance Lₚ can be a predetermined value selected based on creating a three-dimensional (3D) pinch-off effect between shielding structures 306 that enhances protection for both corners of the trenches 310 and adjacent areas. In an embodiment, the distance Lₚ between shielding structures 306 can vary between 0.1 mm and 2.0 mm. Preferably, the distance Lₚ between shielding structures 306 can be of at least 0.1 mm to achieve the 3D pinch-off effect. This approach aims to improve control over electric field distribution and reduce parasitic effects in the semiconductor structure 100.

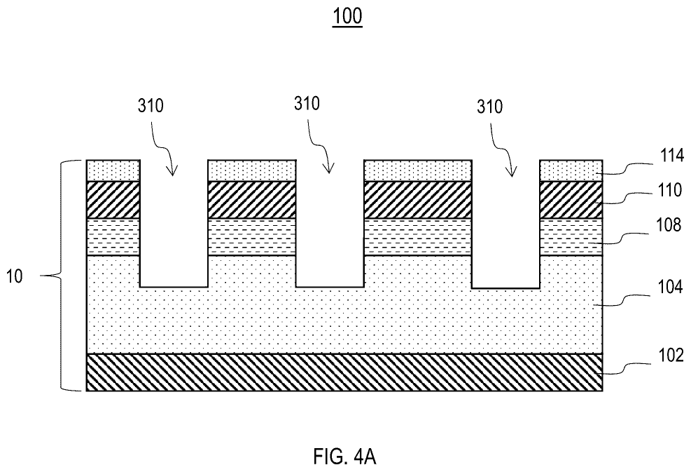

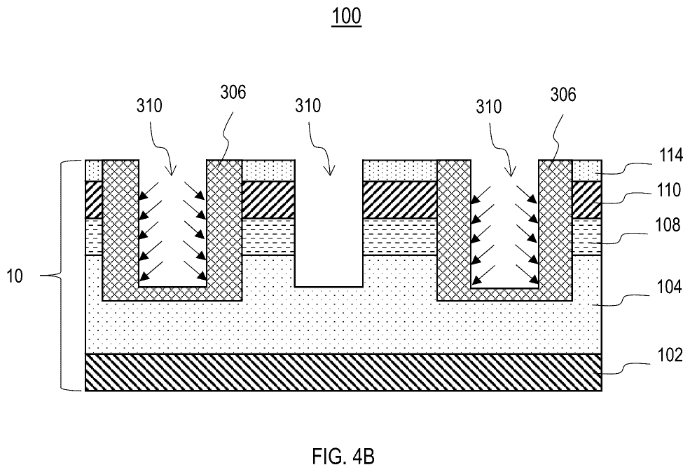

Referring now to FIGS. 4A-4B, cross-sectional views of the semiconductor structure 100 depict an alternate way of forming trenches 310 and shielding structures 306, according to another embodiment of the present disclosure. In this embodiment, FIG. 4A and FIG. 4B are cross-sectional views of the semiconductor structure 100 taken along line A-A′ as depicted in FIG. 3A.

Alternatively, in some embodiments, trenches 310 can be formed within the stack 10 of doped semiconductor layers prior to forming the shielding structures 306, as depicted in FIG. 4A. In such an instance, the implantation process to form shielding structures 306 can be conducted on sidewalls of the stack 10 exposed by selected trenches 310, as depicted in FIG. 4B.

The implantation process can be a random ion implantation process or a channeled ion implantation process. The implantation process can be carried out until the impurity concentration and thickness specified above for the shielding structures 306 are achieved. Based on design requirements, certain areas of the stack 10, including some trenches 310, are masked during the implantation process to prevent the formation of shielding structures 306 within these regions. Stated differently, some trenches 310 remain unimplanted, allowing the island-like shielding structures 306 to maintain the staggered distribution pattern shown in FIG. 3A.

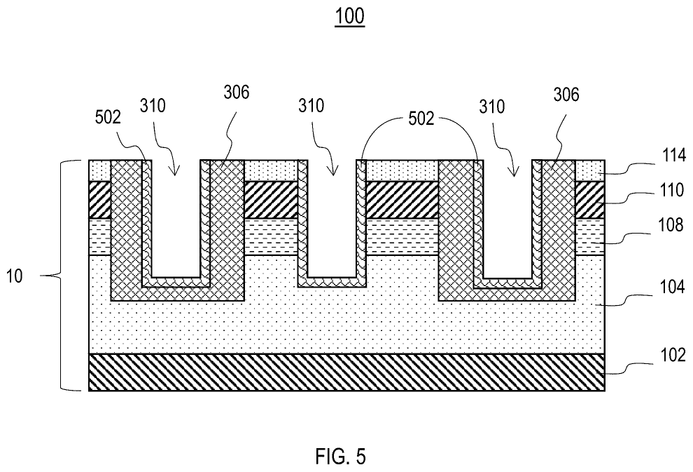

Referring now to FIG. 5, a cross-sectional view of the semiconductor structure 100 is shown after forming an insulating layer 502 within trenches 310, according to an embodiment of the present disclosure. In this embodiment, FIG. 5 is a cross-sectional view of the semiconductor structure 100 taken along line A-A′ as depicted in FIG. 3A.

After forming the shielding structures 306, the fabrication process continues by forming an insulating layer 502 within trenches 310 using various types of deposition processes. The insulating layer 502 can electrically separate a subsequently formed gate electrode from active areas of the semiconductor structure 100. The insulating layer 502 substantially covers opposing vertical sidewalls and an upper surface of the shielding structures 306. The insulating layer 502 also covers regions within the unimplanted trenches 310, specifically those areas of the trenches 310 that are not protected by the shielding structures 306. More particularly, insulating layer 502 is deposited along sidewalls of the source region 114, base region 110, JFET region 108, drift region 104 and above an upper surface of the drift region 104 exposed by unimplanted trenches 310.

In one or more embodiments, the insulating layer 502 can be formed by conformal deposition of a gate insulating film. Non-limiting examples of gate insulating films to form the insulating layer 502 can include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO₂) and the like. In an exemplary embodiment, a thickness of the insulating layer 502 can vary between approximately 10 nm to approximately 100 nm.

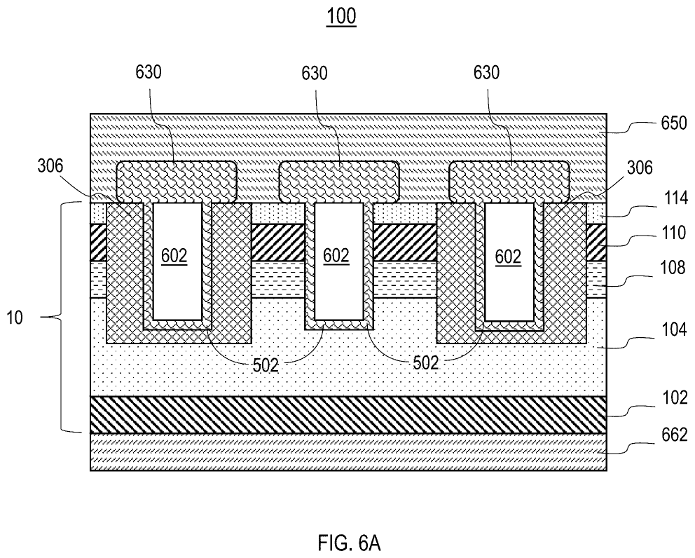

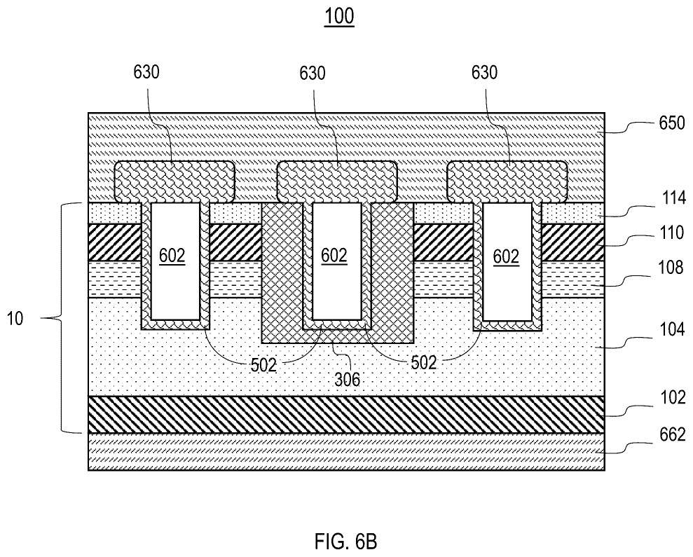

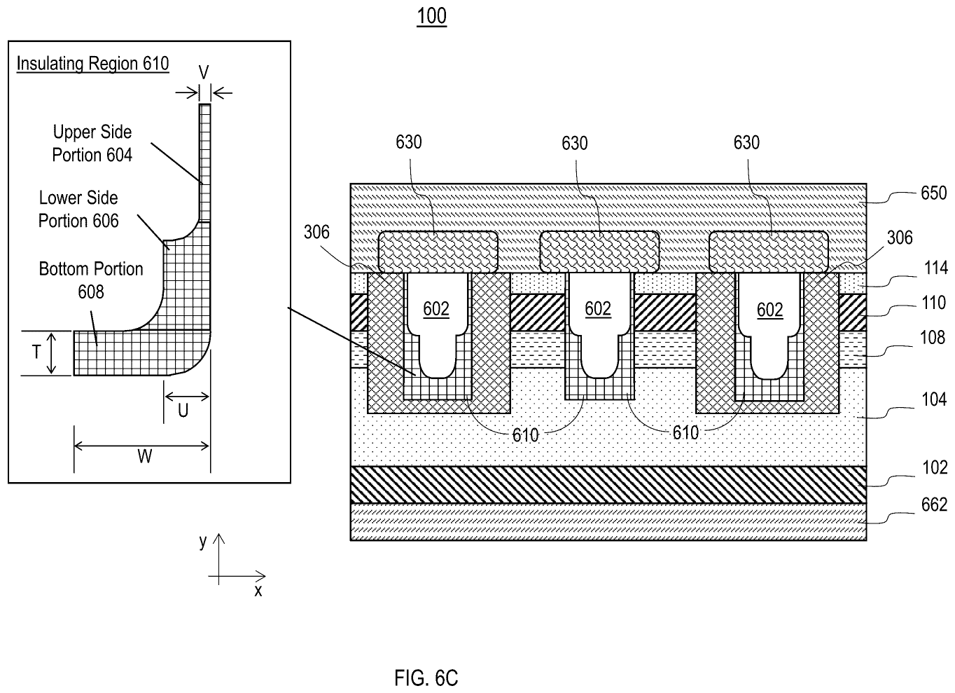

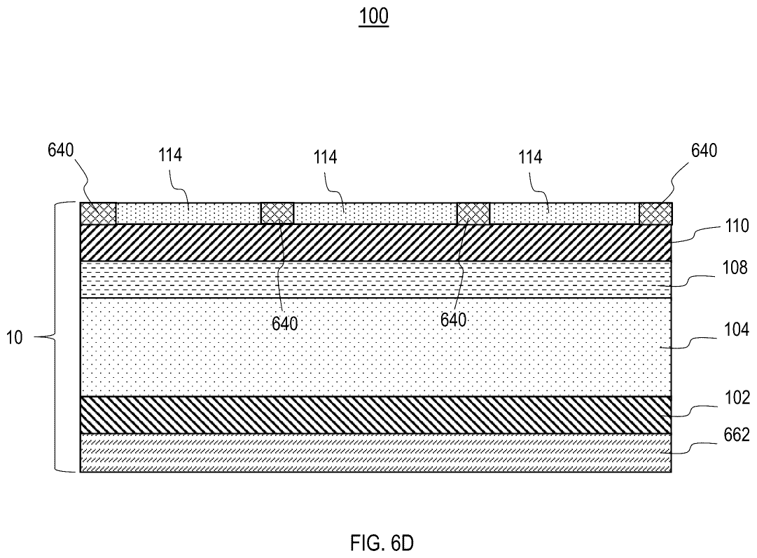

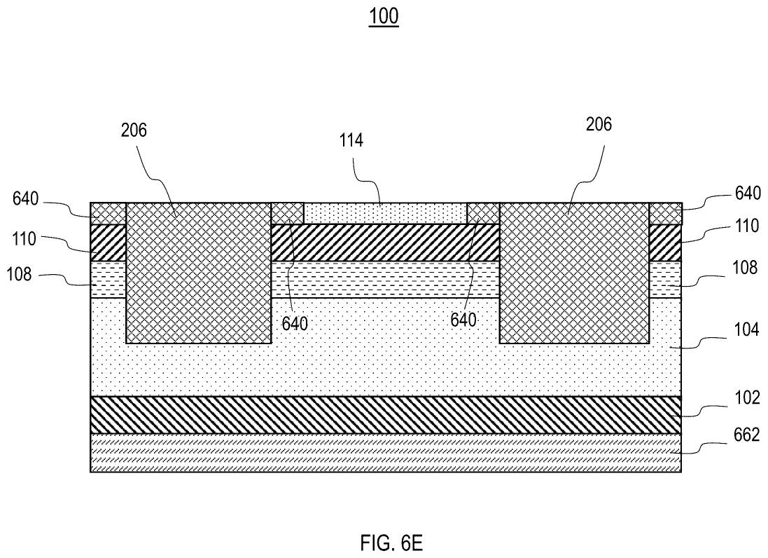

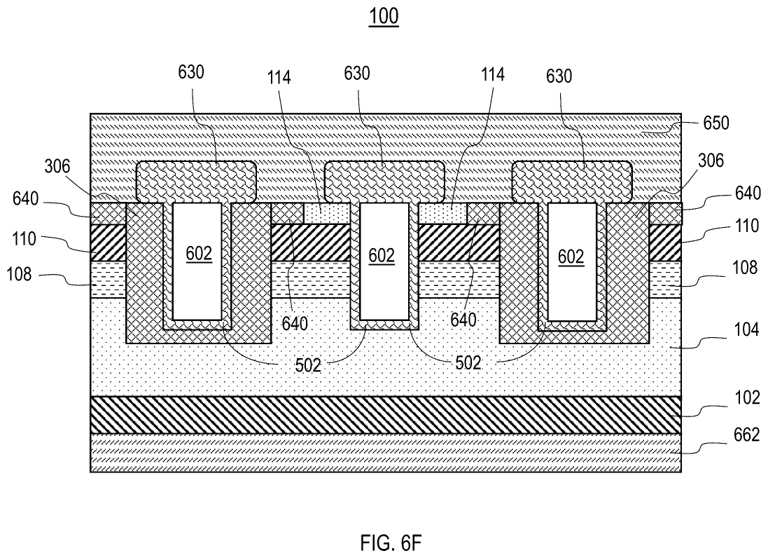

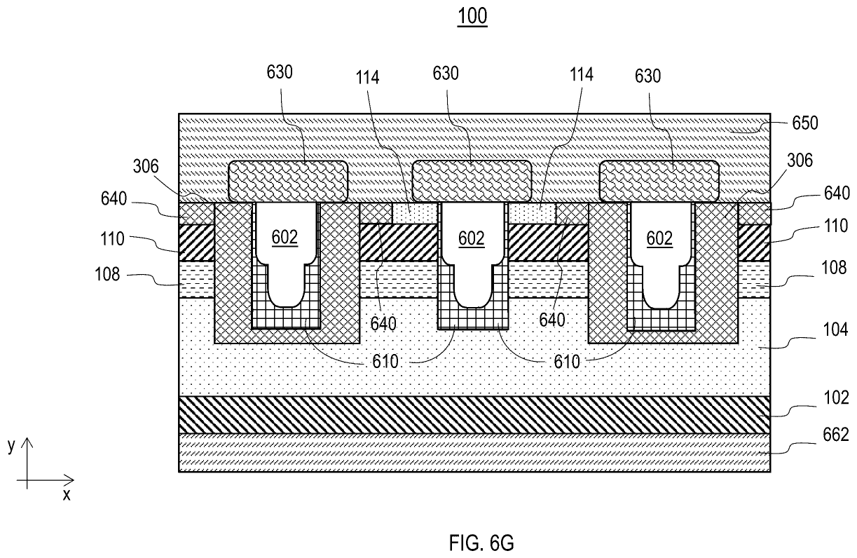

Referring now to FIGS. 6A-6C, cross-sectional views of the semiconductor structure 100 are shown after forming a gate electrode 602, an interlevel dielectric layer 630, top metal layer 650 and bottom metal layer 662, according to an embodiment of the present disclosure. In this embodiment, FIG. 6A is a cross-sectional view of the semiconductor structure 100 taken along line A-A′ as depicted in FIG. 3A, FIG. 6B is a cross-sectional view of the semiconductor structure 100 taken along line B-B′ as depicted in FIG. 3A, and FIG. 6C is a cross-sectional view of the semiconductor structure 100 taken along line A-A′ as depicted in FIG. 3A.

The process of forming the gate electrode 602 can be typical and ordinary in the art. The process usually includes depositing a conductive material, such as polysilicon, within trenches 310 lined with the insulation layer 502. The gate electrode 602 and insulating layer 502 provide a gate structure for the semiconductor structure 100. After forming the gate electrode 602, the interlevel dielectric layer 630 can be formed to fill voids and electrically isolate active regions within the semiconductor structure 100. The interlevel dielectric layer 630 is disposed above an upper surface of the stack 10 of doped semiconductor layers. More particularly, the interlevel dielectric layer 630, as depicted in FIG. 6A, covers an upper surface of the shielding structures 306 and partially covers upper portions of source region 114. In one or more embodiments, the interlevel dielectric layer 630 can be formed by, for example, conformal deposition (e.g., CVD) of a dielectric material such as silicon oxide, silicon nitride, and the like. In one or more embodiments, a patterning process can be conducted on the interlevel dielectric layer 630 to achieve the shape shown in the figures.

In the depicted embodiment, a top metal layer 650 is deposited above the interlevel dielectric layer 630 and exposed portions of the source region 114. The top metal layer 650 provides a source terminal or source electrode that electrically contacts source region 114. In some embodiments, heavily-doped source contacts of the second conductivity type (e.g., P+ source contacts) can be arranged periodically, similar to the island-like shielding structures 306. This arrangement eliminates the need for additional space for source contacts, enabling a more aggressive reduction in cell pitch within the semiconductor structure 100.

A bottom metal layer 662 can be formed on a bottom surface of the substrate 102. The bottom metal layer 662 serves as a drain terminal or drain electrode that provides electrical (ohmic) contact with substrate 102.

With reference now to FIG. 6C, in some embodiments, rather than applying a conformal layer of insulating material like the insulating layer 502 shown in FIGS. 6A-6B, an insulating region with sections of varying thickness can be created within trenches 310. As illustrated in FIG. 6C, an alternative configuration of the semiconductor structure 100 features an insulating region 610 composed of a gate oxide material (e.g., silicon oxide-SiOx) formed within the trenches 310 (shown in FIG. 5) through a two-step oxidation process. This two-step process enables precise control over a thickness of the bottom portion of the insulating region 610.

Particularly, a thinner layer of insulating material (e.g., gate oxide) can provide relatively more efficient control over the channel and a thicker layer of insulating material can prevent gate oxide breakdown. The threshold voltage of semiconductor structure 100 can also be controlled by the thickness of the insulating material forming the insulating region 610. If the electric field in drift region 104 is too high, the insulating material can degrade over time and negatively impact the overall lifespan and reliability of semiconductor structure 100. The oxide degradation can lead to shifts in the threshold voltage. For trench MOSFETs, the trench tends to have a relatively deeper profile (e.g., along the y-axis) compared to its width (e.g., x-axis). Thus, the electric field lines tend to concentrate at the bottom of the trench causing the electric field underneath the trench (e.g., −y direction) to be higher than other regions, such as near the sidewalls of the trench.

As shown in FIG. 6C, insulating region 610 can include an upper side portion 604, a lower side portion 606 and a bottom portion 608. A thickness of upper side portion 604 is labeled as V. A thickness of lower side portion 606 is labeled as U. A thickness of bottom portion 608 is labeled as T. The thickness U and the thickness T can be greater than the thickness V. The thickness U and T can be the same or can be different.

Bottom portion 608 can be in contact with shielding structures 306. Bottom portion 608 and shielding structures 306 can contribute to reduction of electric field in drift region 104 near the bottom of trenches 310 (FIG. 5). Upper side portion 604 can be in contact with at least one of source region 114, base region 110 and JFET region 108. Lower side portion 606 can be in contact with at least JFET region 108 and drift region 104. Lower side portion 606 can contribute to further reduction of electric field in drift region 104 near portions of the sidewalls and corners of trenches 310 (FIG. 5).

In an embodiment, a thickness V of the upper side portion 604 can vary between approximately 1 nm to 20 nm, a thickness T of the bottom portion 608 can vary between approximately 1 nm to 500 nm, and a thickness U of the lower side portion 606 can vary between approximately 1 nm to 500 nm.

Referring now to FIGS. 6D-6G cross-sectional views of the semiconductor structure 100 taken along line A-A′, as depicted in FIG. 3A, are shown depicting an alternate way of forming shielding structures 306, according to an embodiment of the present disclosure.

In this embodiment, FIG. 6D illustrates the formation of shielding regions 640 within specific areas of the source region 114. Shielding regions 640 can be formed using various ion implantation processes, with an impurity concentration of the second conductivity type ranging from approximately 1×10¹⁹ cm⁻³ to approximately 1×10²¹ cm⁻³. The placement of each shielding region 640 within the source region 114 can be tailored to meet specific design requirements. In some embodiments, shielding regions 640 can be formed similarly to the heavily-doped semiconductor regions 206, having comparable impurity concentrations.

FIG. 6E illustrates the formation of heavily-doped semiconductor regions 206 in areas of the stack 10 situated between two adjacent shielding regions 640. The process of forming heavily-doped regions 206 is detailed above with reference to FIG. 2. This alternative fabrication process enables the placement of shielding layers on either side of the heavily-doped semiconductor regions 206 and next to source region 114. In an embodiment, the shielding regions 640 serve as lateral extensions of the second conductivity type, positioned next to the source region 114 and along the upper part of the shielding structures 306. This arrangement can further enhance electric field management.

FIG. 6F depicts the semiconductor structure 100, including shielding regions 640, after forming the gate electrode 602, interlevel dielectric layer 630, top metal layer 650 and bottom metal layer 662. In this embodiment, the shielding effect of shielding structures 306 is further strengthened by the inclusion of shielding regions 640 on opposite top sides of each shielding structure 306. In FIG. 6G semiconductor structure 100 is shown featuring shielding regions 640 positioned on opposite top sides of shielding structures 306 and the insulating region 610 having sections of varying thickness described above with reference to FIG. 6C.

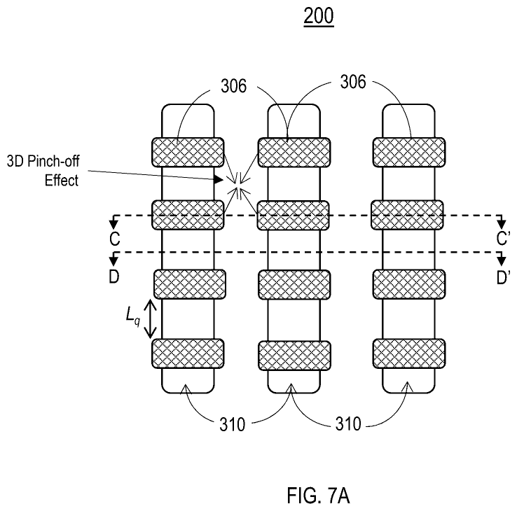

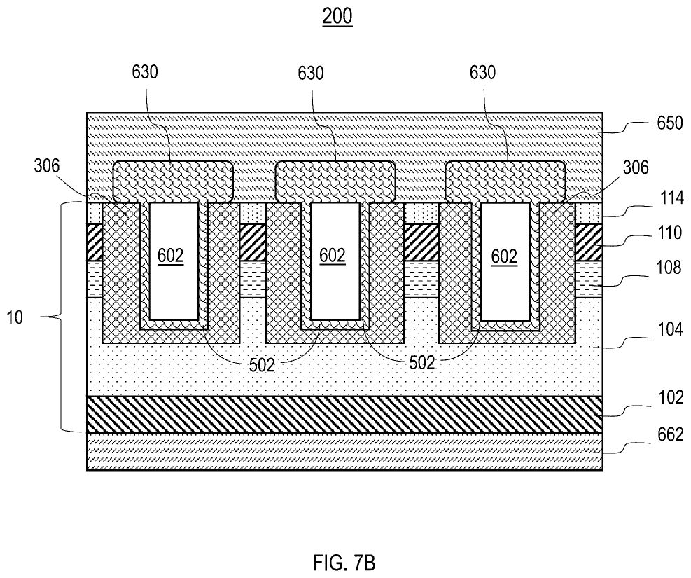

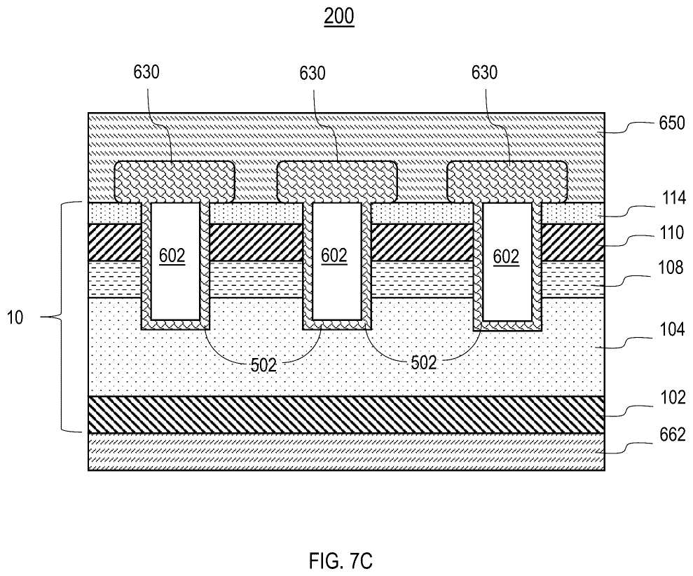

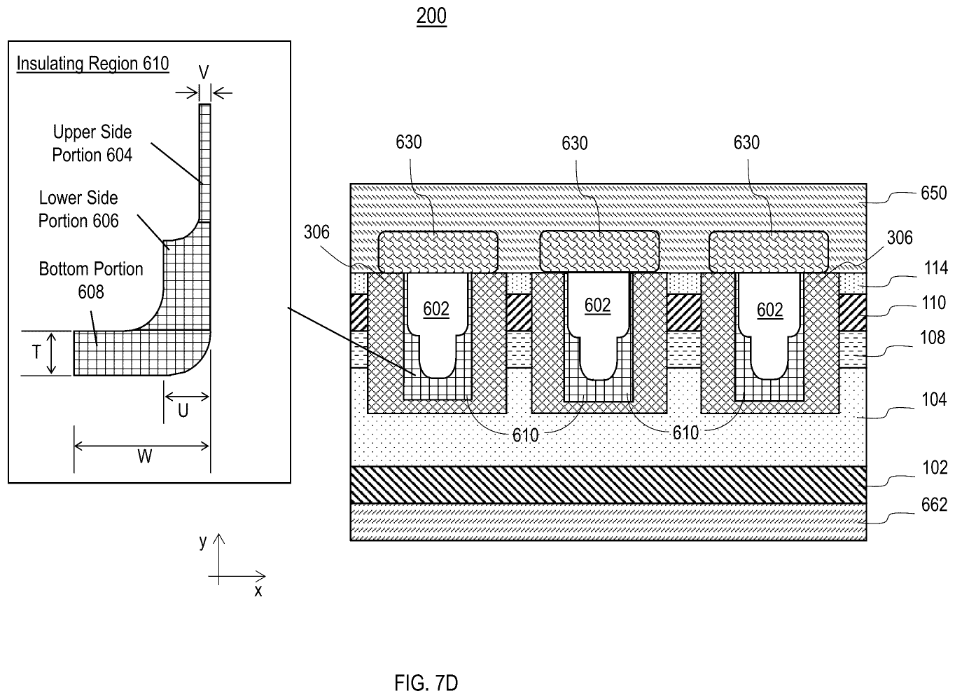

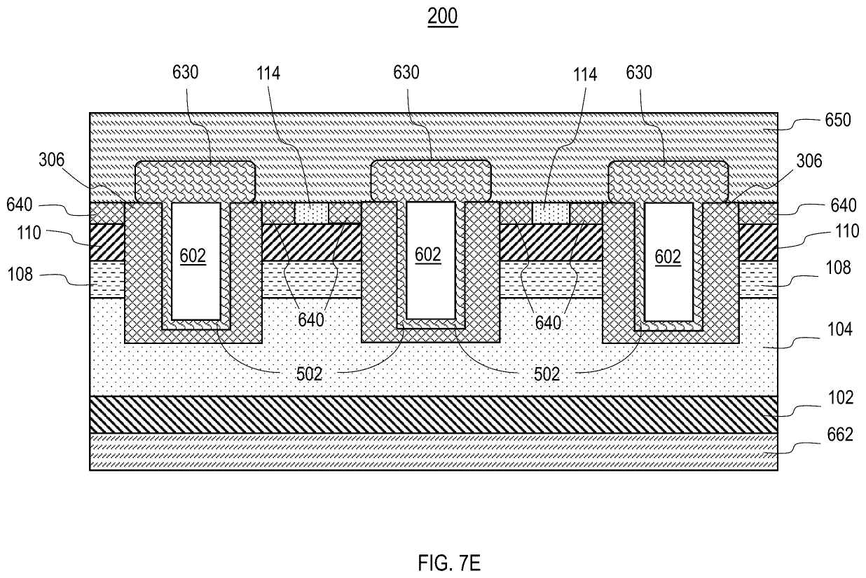

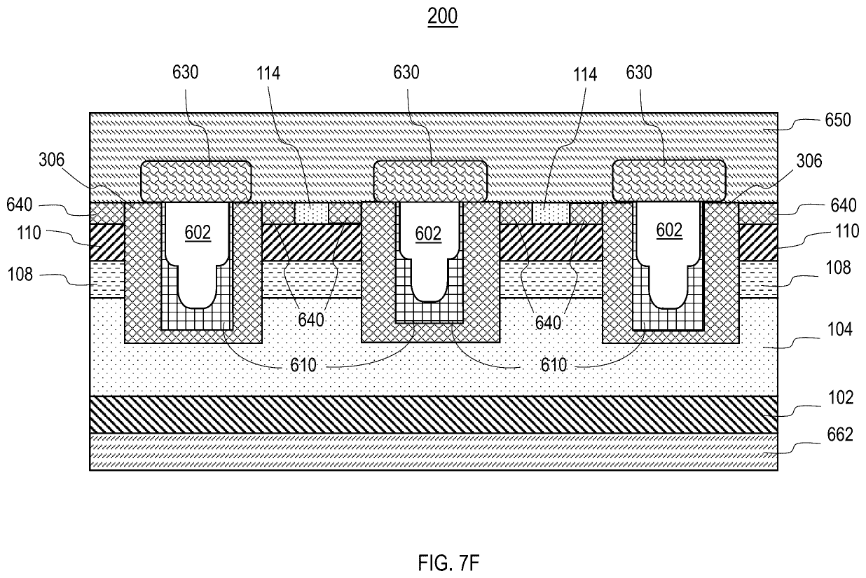

Referring now to FIGS. 7A-7D, different views of a semiconductor structure 200 are shown after forming trenches 310 and shielding structures 306 using a second distribution pattern, according to an embodiment of the present disclosure. In this embodiment, FIG. 7A is a top-down view of the semiconductor structure 200, FIG. 7B is a cross-sectional view of the semiconductor structure 200 taken along line C-C′ as depicted in FIG. 7A, FIG. 7C is a cross-sectional view of the semiconductor structure 200 taken along line D-D′ as depicted in FIG. 7A, and FIG. 7D is a cross-sectional view of the semiconductor structure 200 taken along line C-C′ as depicted in FIG. 7A.

In this embodiment, shielding structures 306 are formed according to a second distribution pattern. The second distribution pattern includes an aligned pattern of isolated clusters or segments, with each cluster resembling an “island”. The island-like shielding structures 306 are positioned in contiguous equidistant regions within trenches 310, with adjacent shielding structures 306 being separated by a distance L_{q}, as shown in FIG. 7A. As explained above, the distance L_{q} can be a predetermined value that can create a 3D pinch-off effect between shielding structures 306 that enhances protection for both corners of the trenches 310 and adjacent areas. The distance of L_{q} can be the same as the distance Lₚ shown in FIG. 3A, or can be different from Lₚ. In an embodiment, the distance L_{q} between shielding structures 306 arranged in an aligned pattern can vary between 0.1 mm and 2.0 mm. Preferably, the distance L_{q} between shielding structures 306 can be of at least 0.1 mm to achieve the 3D pinch-off effect.

FIG. 7D illustrates a scenario where the semiconductor structure 200 is formed using the aligned distribution pattern. However, instead of the conformal insulation layer 502, this structure incorporates the insulation region 610, which features sections of varying thickness, as previously described in relation to FIG. 6C.

Referring now to FIGS. 7E-7F cross-sectional views of the semiconductor structure 200 taken along line C-C′, as depicted in FIG. 7A, are shown depicting shielding regions 640, according to an embodiment of the present disclosure.

FIG. 7E depicts the semiconductor structure 200 including shielding regions 640 after forming the gate electrode 602, interlevel dielectric layer 630, top metal layer 650 and bottom metal layer 662. As mentioned above, the shielding effect of shielding structures 306 is further strengthened by the inclusion of shielding regions 640 on opposite top sides of each shielding structure 306. In this embodiment, shielding structures 306 are positioned following the aligned or second distribution pattern shown in FIG. 7A. In FIG. 7E semiconductor structure 200 is shown featuring shielding regions 640 positioned on opposite top sides of shielding structures 306 and the insulating region 610 having sections of varying thickness described above with reference to FIG. 6C.

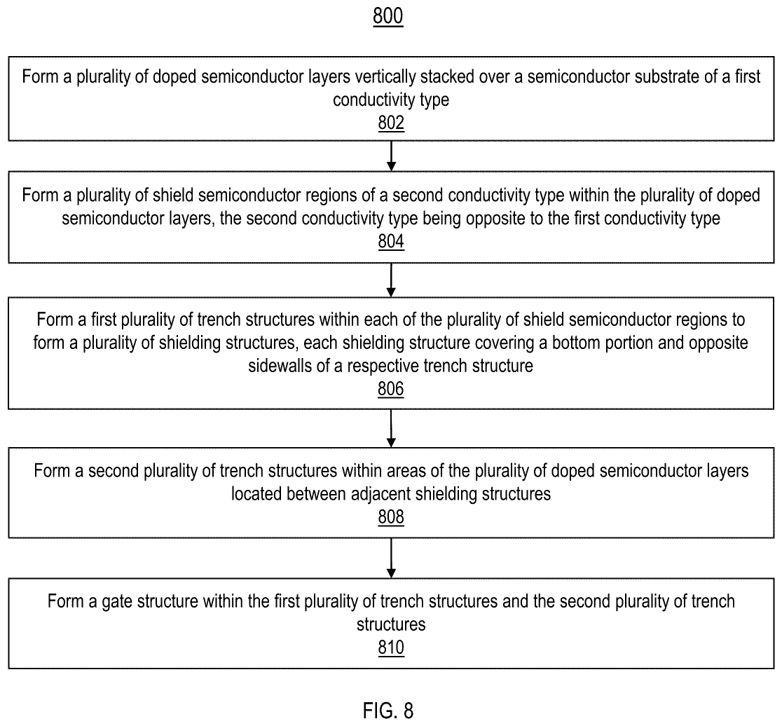

Referring now to FIG. 8, a flowchart 800 depicting operational steps for the fabrication of a semiconductor structure is shown, according to an embodiment of the present disclosure.

The process of forming the semiconductor structure starts at step 802 by forming a plurality of doped semiconductor layers vertically stacked over a semiconductor substrate of a first conductivity type. The semiconductor substrate is made of silicon carbide. In an embodiment, forming the plurality of doped semiconductor layers vertically stacked over the semiconductor substrate further includes forming a drift region of the first conductivity type above the semiconductor substrate, forming a JFET region of the first conductivity type above the drift region, forming a base region of the second conductivity type above the JFET region, the base region including a channel region located along sides of the first plurality of trench structures and the second plurality of trench structures, and forming a source region of the first conductivity type above the base region.

The process continues at step 804 by forming a plurality of shield semiconductor regions of a second conductivity type within the plurality of doped semiconductor layers. The second conductivity type is opposite to the first conductivity type. In an embodiment, forming the plurality of shield semiconductor regions of the second conductivity type further includes implanting selected regions of the plurality of doped semiconductor layers such that each resulting shielding structure includes a heavily doped semiconductor region with an impurity concentration at least 10 times greater than an impurity concentration in the drift region. In an embodiment, implanting the selected regions of the plurality of doped semiconductor layers includes conducting at least one of a random ion implantation process or a channeled ion implantation process.

The process continues at step 806 by forming a first plurality of trench structures within each of the plurality of shield semiconductor regions to form a plurality of shielding structures. Each shielding structure is formed along a bottom portion and opposite sidewalls of a respective trench structure. According to an embodiment, the plurality of shielding structures is configured in an island-like manner following a first distribution pattern and separated by a distance selected based on creating a 3D pinch-off effect between adjacent shielding structures. For example, the distance separating the plurality of shielding structures is at least 0.1 mm. In an embodiment, the first distribution pattern includes a staggered distribution pattern. In another embodiment, the first distribution pattern includes an aligned distribution pattern.

The process continues at step 808 by forming a second plurality of trench structures within areas of the plurality of doped semiconductor layers located between adjacent shielding structures. It should be noted that the first plurality of trench structures and the second plurality of trench structures are formed simultaneously within the plurality of shield semiconductor regions and within areas of the plurality of doped semiconductor layers located between adjacent shielding structures.

Finally, at step 810, a gate structure is formed within the first plurality of trench structures and the second plurality of trench structures. In an embodiment, forming the gate structure further includes conformally depositing an insulating layer within the first trench structures and the second trench structures, and depositing a gate electrode within the first trench structures and the second trench structures lined with the insulating layer. In one or more embodiments, the process further includes forming an interlevel dielectric layer above the gate structure, the interlevel dielectric layer partially extending above an upper surface of the plurality of doped semiconductor layers, forming a source terminal electrically connected to the source region, and forming a drain terminal electrically connected to the semiconductor substrate.

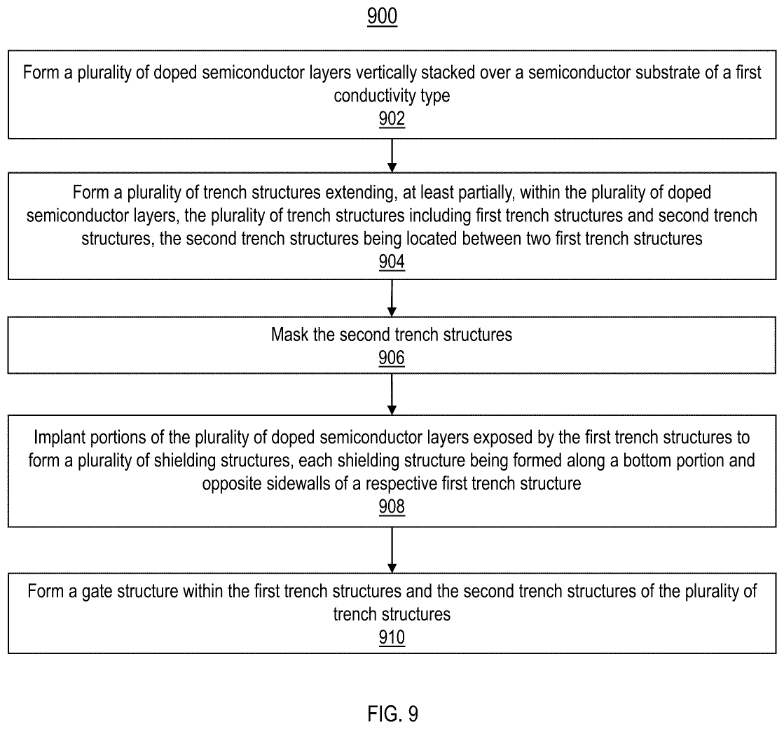

FIG. 9 is a flowchart depicting alternative operational steps for the fabrication of the semiconductor structure, according to another embodiment of the present disclosure.

The alternative process starts at step 902 by forming a plurality of doped semiconductor layers vertically stacked over a semiconductor substrate of a first conductivity type. In an embodiment, the semiconductor substrate is made of silicon carbide. In one or more embodiments, forming the plurality of doped semiconductor layers vertically stacked over the semiconductor substrate further includes forming a drift region of the first conductivity type above the semiconductor substrate, forming a JFET region of the first conductivity type above the drift region, forming a base region of the second conductivity type above the JFET region, the base region including a channel region located along sides of the first plurality of trench structures and the second plurality of trench structures, and forming a source region of the first conductivity type above the base region.

The process continues at step 904 by forming a plurality of trench structures extending, at least partially, within the plurality of doped semiconductor layers. The plurality of trench structures includes first trench structures and second trench structures. The second trench structures are located between two first trench structures.

The process continues at step 906 by masking the second trench structures.

The process continues at step 908 by implanting portions of the plurality of doped semiconductor layers exposed by the first trench structures to form a plurality of shielding structures, each shielding structure covering a bottom portion and opposite sidewalls of a respective first trench structure. According to an embodiment, the plurality of shielding structures is configured in an island-like manner following a first distribution pattern and separated by a distance selected based on creating a 3D pinch-off effect between adjacent shielding structures. For example, the distance separating the plurality of shielding structures is at least 0.1 mm. In an embodiment, the first distribution pattern includes a staggered distribution pattern. In another embodiment, the first distribution pattern includes an aligned distribution pattern.

The process of implanting the portions of the plurality of doped semiconductor layers exposed by the first trench structures to form the plurality of shielding structures includes implanting the exposed portions of the plurality of doped semiconductor layers until each resulting shielding structure includes a heavily-doped semiconductor region with an impurity concentration at least 10 times greater than an impurity concentration in the drift region. In an embodiment, implanting the portions of the plurality of doped semiconductor layers exposed by the first trench structures to form the plurality of shielding structures includes conducting at least one of a random ion implantation process or a channeled ion implantation process.

Finally, at step 910, a gate structure is formed within the first trench structures and the second trench structures of the plurality of trench structures. In an embodiment, forming the gate structure further includes unmasking the second trench structures, conformally depositing an insulating layer within the first trench structures and the second trench structures, and depositing a gate electrode within the first trench structures and the second trench structures lined with the insulating layer. In one or more embodiments, the process further includes forming an interlevel dielectric layer above the gate structure, the interlevel dielectric layer partially extending above an upper surface of the plurality of doped semiconductor layers, forming a source terminal electrically connected to the source region, and forming a drain terminal electrically connected to the semiconductor substrate.

### EXAMPLES

Example 1. A method of forming a semiconductor structure, comprising:
forming a plurality of doped semiconductor layers vertically stacked over a semiconductor substrate of a first conductivity type, wherein the semiconductor substrate is made of silicon carbide;
forming a plurality of shield semiconductor regions of a second conductivity type within the plurality of doped semiconductor layers, the second conductivity type being opposite to the first conductivity type;
forming a first plurality of trench structures within each of the plurality of shield semiconductor regions to form a plurality of shielding structures, each shielding structure covering a bottom portion and opposite sidewalls of a respective trench structure, the plurality of shielding structures being configured in an island-like manner following a first distribution pattern and separated by a distance selected based on creating a 3D pinch-off effect between adjacent shielding structures;
forming a second plurality of trench structures within areas of the plurality of doped semiconductor layers located between adjacent shielding structures; and
forming a gate structure within the first plurality of trench structures and the second plurality of trench structures.

Example 2. The method according to Example 1, wherein forming the gate structure further comprises:
conformally depositing an insulating layer within the first trench structures and the second trench structures; and
depositing a gate electrode within the first trench structures and the second trench structures lined with the insulating layer.

Example 3. The method according to any one of Examples 1 and 2, wherein forming the plurality of doped semiconductor layers vertically stacked over the semiconductor substrate further includes:
forming a drift region of the first conductivity type above the semiconductor substrate; forming a JFET region of the first conductivity type above the drift region;
forming a base region of the second conductivity type above the JFET region, the base region including a channel region located along sides of the first plurality of trench structures and the second plurality of trench structures; and
forming a source region of the first conductivity type above the base region.

Example 4. The method according to any one of Examples 1 to 3, wherein the first distribution pattern includes a staggered distribution pattern.

Example 5. The method according to any one of Examples 1 to 4, wherein the first distribution pattern includes an aligned distribution pattern.

Example 6. The method according to any one of Examples 1-5, wherein forming the plurality of shield semiconductor regions of the second conductivity type further includes:
implanting selected regions of the plurality of doped semiconductor layers such that each resulting shielding structure includes a heavily doped semiconductor region with an impurity concentration at least 10 times greater than an impurity concentration in the drift region.

Example 7. The method according to any one of Examples 1-6, wherein implanting the selected regions of the plurality of doped semiconductor layers comprises:
conducting at least one of a random ion implantation process or a channeled ion implantation process.

Example 8. The method according to any one of Examples 1-7, wherein the distance separating the plurality of shielding structures is at least 0.1 mm.

Example 9. The method according to any one of Examples 1-8, further comprising: forming an interlevel dielectric layer above the gate structure, the interlevel dielectric layer partially extending above an upper surface of the plurality of doped semiconductor layers.

Example 10. The method according to any one of Examples 1-9, further comprising:
forming a source terminal electrically connected to the source region; and
forming a drain terminal electrically connected to the semiconductor substrate.

Example 11. A method of forming a semiconductor structure, comprising:
forming a plurality of doped semiconductor layers vertically stacked over a semiconductor substrate of a first conductivity type, wherein the semiconductor substrate is made of silicon carbide;
forming a plurality of trench structures extending, at least partially, within the plurality of doped semiconductor layers, the plurality of trench structures including first trench structures and second trench structures, wherein the second trench structures are located between two first trench structures;
masking the second trench structures;
implanting portions of the plurality of doped semiconductor layers exposed by the first trench structures to form a plurality of shielding structures, each shielding structure covering a bottom portion and opposite sidewalls of a respective first trench structure, the plurality of shielding structures being configured in an island-like manner following a first distribution pattern and separated by a distance selected based on creating a 3D pinch-off effect between adjacent shielding structures; and
forming a gate structure within the first trench structures and the second trench structures of the plurality of trench structures.

Example 12. The method according to Example 11, wherein forming the gate structure further comprises:
unmasking the second trench structures;
conformally depositing an insulating layer within the first trench structures and the second trench structures; and
depositing a gate electrode within the first trench structures and the second trench structures lined with the insulating layer.

Example 13. The method according to any one of Examples 11 and 12, wherein forming the plurality of doped semiconductor layers vertically stacked over the semiconductor substrate further includes:
forming a drift region of the first conductivity type above the semiconductor substrate;
forming a JFET region of the first conductivity type above the drift region;
forming a base region of the second conductivity type above the JFET region, the base region including a channel region located along sides of the first plurality of trench structures and the second plurality of trench structures; and
forming a source region of the first conductivity type above the base region.

Example 14. The method according to any one of Examples 11-13, wherein the first distribution pattern includes a staggered distribution pattern.

Example 15. The method according to any one of Examples 11-14, wherein the first distribution pattern includes an aligned distribution pattern.

Example 16. The method according to any one of Example 11-15, wherein implanting the portions of the plurality of doped semiconductor layers exposed by the first trench structures to form the plurality of shielding structures includes:
implanting the exposed portions of the plurality of doped semiconductor layers until each resulting shielding structure includes a heavily doped semiconductor region with an impurity concentration at least 10 times greater than an impurity concentration in the drift region.

Example 17. The method according to any one of Example 11-16, wherein implanting the portions of the plurality of doped semiconductor layers exposed by the first trench structures to form the plurality of shielding structures includes:
conducting at least one of a random ion implantation process or a channeled ion implantation process.

Example 18. The method according to any one of Examples 11-17, wherein the distance separating the plurality of shielding structures is at least 0.1 mm.

Example 19. The method according to any one of Examples 11-18, further comprising: forming an interlevel dielectric layer above the gate structure, the interlevel dielectric layer partially extending above an upper surface of the plurality of doped semiconductor layers.

Example 20. The method according to any one of Example 11-19, further comprising:
forming a source terminal electrically connected to the source region; and
forming a drain terminal electrically connected to the semiconductor substrate.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor substrate of a first conductivity type, the semiconductor substrate including silicon carbide;
a drift layer of the first conductivity type located above the semiconductor substrate;
a channel layer of a second conductivity type located above the drift layer, the second conductivity type of the channel layer being opposite to the first conductivity type of the drift layer;
a source region of the first conductivity type located above the channel layer;
a plurality of trenches penetrating through the source region, the channel layer and a portion of the drift layer;
a gate electrode located within each of the plurality of trenches via a gate insulating film; and
a plurality of shielding structures of the second conductivity type located around the gate electrode, wherein the plurality of shielding structures covers sidewalls and a bottom of the plurality of the trenches, the plurality of shielding structures being arranged in an island-like manner.

2. The semiconductor structure according to claim 1, wherein the plurality of shielding structures is arranged in a staggered pattern.

3. The semiconductor structure according to claim 1, wherein the plurality of shielding structures is arranged in an aligned pattern.

4. The semiconductor structure according to claim 1, wherein the plurality of shielding structures are separated by a predetermined interval in a first direction, and the predetermined interval is 0.1 mm or more and 2.0 mm or less.

5. The semiconductor structure according to claim 1, wherein the plurality of shielding structures includes an impurity concentration at least 10 times greater than an impurity concentration in the drift layer.

6. A semiconductor structure, comprising:
a plurality of trench structures extending, at least partially, within a stack of doped semiconductor layers, the plurality of trench structures including first trench structures and second trench structures, wherein the second trench structures are located between two adjacent first trench structures;
a gate structure disposed within the first trench structures and the second trench structures; and
a plurality of shielding structures embedded, at least partially, within the stack of doped semiconductor layers surrounding the gate structure within the first trench structures, the plurality of shielding structures being separated by a distance selected based on initiating a three-dimensional pinch-off effect between adjacent shielding structures,
wherein the gate structure within the second trench structures is surrounded by the stack of doped semiconductor layers.

7. The semiconductor structure according to claim 6, wherein the gate structure further includes:
an insulating layer lining the first trench structures and the second trench structures; and
a gate electrode disposed above the insulating layer.

8. The semiconductor structure according to claim 6, wherein the plurality of shielding structures are configured in an island-like manner.

9. The semiconductor structure according to claim 6, wherein the plurality of shielding structures are distributed following a staggered pattern.

10. The semiconductor structure according to claim 6, wherein the plurality of shielding structures are distributed following an aligned pattern.

11. The semiconductor structure according to claim 6, wherein the stack of doped semiconductor layers includes:
a semiconductor substrate of a first conductivity type, the semiconductor substrate being made of silicon carbide;
a drift region of the first conductivity type located above the semiconductor substrate;
a JFET region of the first conductivity type located above the drift region;
a base region of a second conductivity type disposed above the JFET region, the second conductivity type being opposite to the first conductivity type, the base region including a channel region located along the plurality of trench structures; and
a source region of the first conductivity type located above the base region.

12. The semiconductor structure according to claim 11, further comprising:
a source terminal electrically connected to the source region; and
a drain terminal electrically connected to the semiconductor substrate.

13. The semiconductor structure according to claim 6, wherein the distance separating the plurality of shielding structures is at least 0.1 mm.

14. A semiconductor structure, comprising:
a semiconductor substrate of a first conductivity type, the semiconductor substrate including silicon carbide;
a drift layer of the first conductivity type located above the semiconductor substrate;
a channel layer of a second conductivity type located above the drift layer, the second conductivity type of the channel layer being opposite to the first conductivity type of the drift layer;
a source region of the first conductivity type located above the channel layer;
a plurality of trenches penetrating through the source region, the channel layer and a portion of the drift layer;
an insulating region lining the plurality of trenches, wherein the insulating region includes a bottom portion, a lower side portion and an upper side portion;
a gate electrode located within each of the plurality of trenches lined with the insulating region; and
a plurality of shielding structures of the second conductivity type located around the gate electrode, wherein the plurality of shielding structures covers sidewalls and a bottom of the plurality of the trenches, the plurality of shielding structures being arranged in an island-like manner.

15. The semiconductor structure according to claim 14, wherein a thickness of the bottom portion of the insulating region is greater than a thickness of the upper side portion of the insulating region.

16. The semiconductor structure according to claim 14, wherein a thickness of the lower side portion of the insulating region is greater than the thickness of the upper side portion.

17. The semiconductor structure according to claim 14, wherein the plurality of shielding structures is arranged in a staggered pattern.

18. The semiconductor structure according to claim 14, wherein the plurality of shielding structures is arranged in an aligned pattern.

19. The semiconductor structure according to claim 14, wherein the plurality of shielding structures are separated by a predetermined interval in a first direction, and the predetermined interval is 0.1 μm or more and 2.0 μm or less.

20. The semiconductor structure according to claim 14, wherein the plurality of shielding structures includes an impurity concentration at least 10 times greater than an impurity concentration in the drift layer.
